(19) United States
(12) Patent Application Publication
(10) Pub. No.: US 2017/0256697 A1
(43) Pub. Date: Sep. 7, 2017

(54) Thermoelectric device and manufacturing process therefor

(71) Applicant: CASTFUTURA S.P.A., Terno d'Isola (BG) (IT)

(72) Inventors: Giorgio Offredi, Galbiate (LC) (IT); Fabio Pozzi, Calolziocorte (LC) (IT)

(21) Appl. No.: 15/447,115

(22) Filed: Mar. 2, 2017

(30) Foreign Application Priority Data
Mar. 4, 2016 (IT) 102016000022829

(51) Int. Cl. H01L 35/32; H01L 35/10

(52) U.S. Cl. CPC H01L 35/325; H01L 35/10

(57) ABSTRACT

The invention relates to a thermoelectric device including a pair of different conductors joined at one head end to form a thermocouple junction, the opposite tail ends being free. The conductors have a circular or elliptical section, are arranged side-by-side in proximity of the head end and are joined by laser welding. Several pairs of conductors may be connected together by joining also the tail ends of a conductor of a pair with the tail end of the different conductor of another pair to form a thermopile comprising thermocouple junctions in series. The invention further relates to a process of manufacturing the device.

### FIELD OF THE INVENTION

The present invention relates to a thermoelectric device able to generate electric voltage when subjected to temperature gradient.

### BACKGROUND OF THE INVENTION

Such devices are known and widely used for measuring temperatures or for driving control members as a function of temperature changes. For example think of the field of burners where it is necessary to detect the temperature of the burning surface or more simply the presence of flame.

Known devices use the principle according to which, in a circuit composed of two dissimilar conductors, subjected to a temperature gradient, a difference in potential occurs. Such phenomenon, called a Seeback effect, is the base of the operation of thermocouples.

Thermocouples are composed of two dissimilar conductors joined at one end, called also as hot junction. The opposite free ends are conventionally called as cold junction. A temperature difference between the region of the hot junction and the region of the cold junction causes an electric potential difference between the free ends of the thermocouple at the cold junction.

In order to increase the detectable voltage it is known to place several thermocouples in series such to form a thermopile, widely used in the burner field. A thermopile composed of n thermocouples at its ends has a potential difference n times higher than that of the single thermocouple clearly enhancing sensitivity.

U.S. Pat. No. 2,677,712 discloses the typical structure of a thermopile. In practice, it is a plurality of thermocouples composed of pairs of dissimilar conductors joined together at their upper ends. Thermocouples in turn are interconnected at their lower ends to form a series.

Conventional thermopiles comprise a thermoelectric generator which is composed of a plurality of first and second metal elements, the first metal elements being made of the same metal and the second metal elements being also made of the same metal and the metal of the first elements being different from the metal of the second elements, while the first and second metal elements are connected to an electrically conductive junction and also mechanically, in series alternately with each other, a first metal element being connected in two different points to a second metal element respectively and a second metal element being connected in different points to a first metal element, said metal elements being electrically insulated from each other in regions not coinciding with the regions joining to a further element, while the signal is taken by a conductor connected to the free end of an initial metal element of the sequence of alternate first and second metal elements and to an end metal element of said sequence of alternate first and second metal elements.

In known thermopiles, this thermoelectric generator, in the form of a strip or a ribbon, is compressed for example by being wound and it is housed in a holding case together with incoherent filling material.

The holding case for example is in the form of a tube closed at one end, while the opposite end is closed by fastening a cap or cup terminal having holes for the passage of the two signal capturing conductors.

One of the most critical parts in the manufacturing process is forming the junctions, namely welding the dissimilar conductors in proximity of the ends. Such junctions have to be electrically conductive and mechanically stable over time.

In the use of thermopiles for energizing control electromagnets associated to gas regulator valves, for example a burner, the electric energy generated by the thermopile has to be enough for energizing the electromagnet such to open the valve. In this case the thermopile is subjected to the flame during an initial step when the opening of the valve is guaranteed by a manual action exerted on a control member of the valve that has to be maintained till the signal generated by the thermopile is enough for energizing the electromagnet controlling the valve, that is opening the valve. In this case the manual action can be stopped with the valve that does not automatically close stopping gas supply. If the electric signal generated by the thermopile is not enough to efficaciously energize the electromagnet, namely for operating the valve in the open condition, then the interruption of the manual action causes the valve to close and therefore the flame is turned off and the gas supply is interrupted.

When, on the contrary, a burner provided with a electromagnet-controlled valve is voluntarily turned off, the thermopile has to be able to cool down such to prevent, due to a slow cooling, the generated electric signal from remaining for a long time at such a level to properly energize the electromagnet even with no flame of the burner and therefore preventing the supply from occurring even without the flame during the cooling period.

Therefore, the construction of thermopiles is relatively complicated since the thermopile has to reach quite quickly the optimal temperature to provide the electric signal enough for energizing the electromagnet namely opening the valve. On the other hand the thermopile has also to exhibit relatively short and definite cooling time to allow the electromagnet to de-energize and therefore allowing the valve to pass in the closed condition stable over time and that does not allow supply, even short time supply, with no flame.

Such functional aspects therefore cause constructional difficulties for the thermopile that are quite in conflict with each other. While power and particularly voltage of the electric signal generated by the thermopile depends both on the number of junctions and therefore of elements of different materials, and also on the quality of the electric insulation between the individual metal elements outside the junction regions, thermal inertia depends on the mass and generally it decreases, construction and materials being the same, as the mass itself.

Therefore, both the quality of the junctions is very important in regard to the electric conductivity and also in regard to mechanical stability, and the electric insulation of metal elements composing the sequence of thermocouples of the thermopile, and also an optimal selection of materials and a process of assembling the thermocouple.

Thermopiles are known where the individual metal elements, namely the conductors, have a flattened section shape, therefore upon the connection they have to be aligned and opened wide before being welded by electric welding. This results in the need of rolling and orienting the conductors.

Moreover since conductors are typically covered by insulating oxide, it is necessary to provide a process, defined as ROS (Remove Oxidation Sandblast), for removing oxide near the junction areas generally provided at the ends, such to guarantee the electric continuity necessary for the welding process by electric spot welding.

Such three steps of the manufacturing process are critical, involve additional costs and a lower reliability of the finished product.

Particularly, the electric spot welding step generates a joint region where the different metals, the elements to be connected are made of, form a kind of alloy, by melting together, and such region has an extension substantially limited to the size of the electrodes and also a quite surface extension with reference to the penetration of the melting effect in the thickness of the materials forming the elements to be joined. This actually limits the efficacy of the thermoelectric effect of junctions.

Compared to an ideal, theoretical junction this requires that, for reaching a voltage of the signal generated by the thermopile, a higher number of elements is necessary compared to the theoretical case resulting in a corresponding increase in the mass and in the dimensions of the thermopile and an increase of thermal inertia.

Other critical aspects reside in the materials filling the gaps between metal elements of the thermoelectric generator inside the case.

### SUMMARY OF THE INVENTION

The aim of the present invention is to provide a device solving at least partially such drawbacks forming a simple and cheap alternative to known devices and optimizing the thermopile as regards the delicate and critical balance between power of the generated signal and response time, that is thermal inertia.

The invention achieves the aim by providing a thermoelectric device comprising a pair of different conductor elements joined at one head end such to form a thermocouple junction, the opposite tail ends being free. The conductors have a circular or elliptical cross-section, are arranged side-by-side in proximity of the head end and are joined by laser welding.

Several pairs of conductors can be connected together such to form a thermopile comprising thermocouple junctions in series obtained by joining tail ends of a conductor of a pair with the tail end of the different conductor of another pair, for example by placing side-by-side and laser welding also the conductors in proximity of the tail end.

Thus, a sequence of thermocouples connected together in series is obtained and wherein each metal element is connected to the immediately previous one and the immediately following one only at one of its ends respectively, therefore the assembly of said thermocouples connected in series forms a thermoelectric generator with a zig-zag shape.

As it will be clearer from the following description, laser welding involves a great advantage as regards electric conductivity of the junction. It results that not only the surface of the junction area efficacious for the thermoelectric effect is larger compared to an identical joining condition obtained by electric spot welding, but the depth of the region where the two melted metal materials combine with each other is greater. Therefore, the thermoelectric effect of the single junction is more effective and, under the same power of the signal of the generator obtained by conventional joining techniques, the necessary number of elements by using the technology of the present invention is definitely lower.

At the same time, this involves a greater compactness of the thermopile in its finished shape and, therefore, advantages in thermal inertia and in speed both for reaching the temperature required to provide a useful electric signal and for the speed dropping the temperature under the temperature value, at which the generated electric signal is not enough to energize the electromagnet of a valve or other equipment powered by the thermopile.

Additional advantages in the use of laser welding in combination with round cross-section metal elements are avoiding rolling the metal elements that are generally obtained from a metal wire by sectioning and after further preparation treatments that will be described in the following description.

Moreover, the rotational symmetry of the cross-section shape simplifies a step of aligning the metal elements preparatory for the realization of the junction. By using rounded cross-section elements the elements have only to be placed properly side-by-side at the necessary distance for an optimal laser welding, and aligned with each other with reference to the head ends.

Considering an assembly of metal elements forming a sequence of thermocouples connected in series with each other in the form of a zig-zag shaped element and formed of individual straight elements connected with each other at the corresponding ends, an element of a first metal being followed by an element of a second metal and this latter by a further element composed of the first metal and so on in sequence, the realization of junctions between elements by laser welding allows also a great advantage of mechanical stability over time to be provided and therefore a guarantee of duration over time of the thermopile using such thermoelectric generator.

Once the assembly of metal elements connected together is compressed such to align almost parallel with each other the individual pieces a stress is generated on the connection regions that tends to separate the pieces in the contact region. Such forces are generated by the intrinsic elastic flexibility of the metal pieces urged one against the other by compression and it is discharged on the junctions at the ends thereof, substantially working permanently over time for separating said ends.

Therefore, in the condition compressed into the housing case, junctions are continuously subjected to a stress directed at detaching said ends of the metal pieces and in case of a non optimal mechanical connection it may occur that, over time, two pieces became detached thus interrupting the electric continuity of the generator of the thermopile or under the best hypothesis that the junction region gets narrower and therefore the electric contact is partially compromised reducing performances of the thermopile as regards generated potential difference and/or generated electric power.

Other advantages will be further clear with reference to the various steps manufacturing the thermoelectric generator, for example the fact of avoiding the need of removing covering layers that are provided such as electric insulation jackets of the metal element. By using joint techniques by electric welding such step would be necessary, while in laser welding the electric insulation layers, generally in the form of oxides, do not affect the quality of the junction.

As regards the above, it has to be noted that the insulation layer is generally placed not on the individual elements obtained by sectioning a continuous wire or ribbon, but as a treatment performed before the sectioning and therefore also the provision of a mask of the junction region would not be possible without radically changing the manufacturing process.

Considering a typical and known process for manufacturing a thermopile it provides the main steps of:

For each type of metal, a wire is provided to be used which is subjected to the following treatments:

(a) providing a wire already rolled with a rectangular cross-section, for example with sides of 1.2×0.8

(b) cutting the elements to size

(c) coupling the elements cut to size of the two metals and welding them;

(d) deburring the head of the welded region if cutting has generated flash, such to allow the following step;

(e) washing the assembly of metal elements welded together at the ends such to form a corrugated or zig-zag element;

(f) oxidizing the corrugated element;

(g) winding the corrugated element;

(h) subjecting the corrugated element to thermal treatment, that is baking it to be stabilized in a tubular or cylindrical shape;

(i) providing a tube for housing the corrugated element wound on itself and filling in said housing tube glass in the granular or incoherent form;

(j) inserting the corrugated element wound in the cylindrical shape in said tube;

(k) cooking the glass after drying;

(l) sandblasting the ends of the metal elements forming the corrugated element to which the signal drawing conductors have to be connected;

(m) preparing the drawing conductors together with the fastening nut and pre-inserting into a cap or cup shaped closing terminal of the housing tube;

(n) brazing with silver alloy or the like at high temperature the metal elements intended to draw the signal with the corresponding drawing conductors;

(o) insulating the welds such to avoid short circuiting with the sheath;

(p) filling the cap terminal with cement and fitting on the housing tube;

(q) drying the cement;

(r) performing a functional test to verify that no short circuits to ground of the elements have occurred and that the thermopile has the proper electric resistance.

Such essential steps of the known methods can be made in different manners.

As it will clearer in greater details below, by the invention, compared to the sequence of steps of known systems, it is possible to eliminate three steps of the process of manufacturing known devices.

By using a round wire, it is not necessary to provide a precise positioning of a metal element with respect to the adjacent element to properly align the mutual contact surfaces defined by the cross-section shapes of said elements such that they can have corresponding contact sides properly facing each other.

By using the circular symmetry of the section of the metal elements, it is possible to draw near the elements in any position before welding them, possibly after an axial alignment of the head and/or tail ends, for example by putting one of the ends of the conductors abutting on an abutment surface.

By using laser, then it is not necessary to remove oxide from the terminals since the electric continuity is not more necessary to perform welding.

Particularly, the use of laser welding for the end portions of the metal elements provides for overcoming drawbacks related to oxidation of the corrugated element after the metal elements have been welded.

Since oxidation of the metal elements separated before being welded is not possible with known processes, because electric spot welding would not be possible and therefore it would be necessary to provide a step removing insulation at least at the end portions of the metal elements to be welded, the oxidation for generating the electric insulation layer is carried out after forming the corrugated element. With the corrugated element in the formed condition the oxidation of metal elements has to be performed also in areas immediately adjacent to the weld that however are in contact to or very close to each other, therefore, in said regions the oxidation does not occur or it is not enough to guarantee electric insulation. The result of such defect is that the surface along which the electrical contact between two adjacent metal elements welded together occurs is larger than the region defined by the weld. This is the same as shortening the metal elements and as a reduction in resistance, therefore in order to obtain the same potential difference it is necessary to provide a higher number of elements with respect to what can be obtained by the present invention.

Another advantage of laser welding, that will be detailed below in the present description, is that by using the particular circular symmetry of the cross-section of the metal elements, it is possible to create a welding region containing an amount of melting material higher than in the case of flat conductors, considerably increasing the quality of junction as regards the electric contact and also the consumption of electrodes.

The joining area of the head and/or tail ends of the conductors takes the shape of two semi-cylinders with circular or elliptical base joined along a generating line with gap between said semi-cylinders at least partially occupied by melting material resulting from welding. Thus, a junction with a substantially oval cross-section is formed that is with arc portions joined by straight or curved lines.

Besides a better connection in regard to mechanical strength, the electric contact is also better and, therefore, the effect generating the potential difference generated by two different metals is improved.

In the process according to the present invention in one embodiment it is possible to provide after the step joining the individual metal elements a further oxidation step that is performed after the step welding the individual metal elements and however before compacting the sequence of metal elements and which oxidation step generates a insulating covering layer for the whole sequence of metal elements joined together.

Typically such oxidation step occurs in an oven at a temperature of about 850° C.

In laser welding, the junction area is completely affected by the melting effect of the two materials, therefore there are no contact-only areas and oxidation performed with the metal elements connected to each other does not have areas where the covering can be provided or not provided in a not predictable manner.

According to what disclosed above therefore the invention relates to a method for manufacturing thermopiles which method comprises the following steps:

(a) providing a round wire;

(b) washing the wire;

(c) straightening the wire;

(d) oxidizing the wires made of the two metals and cutting to size;

(e) mating the metal elements obtained from the two wires in a sequence of metal elements side-by-side of different metal, alternately with each other;

(f) laser welding the ends of said metal elements for a given length of the end portions;

(g) winding the corrugated or zig-zag element on itself;

(h) stabilization thermal treatment, that is baking for stabilizing in tubular or cylindrical shape the corrugated or zig-zag element;

(i) providing a housing tube and insulating the element housing tube by one of the following manners as an alternative or in any combination:

(i1) lining the inner wall of the housing tube with a thin layer of high temperature cement that then has to be dried;

(i2) lining the inner wall of the housing tube with mica-based insulating paper with high temperature resistance;

(j) inserting glass in the housing tube;

(k) inserting the corrugated element wound and stabilized with the cylinder shape in the housing tube;

(l) possibly vibrating the housing tube with the glass and the corrugated element inserted therein and baking the glass;

(m) preparing the drawing conductors together with the fastening nut and pre-inserting in a cap or cup closing terminal of the housing tube;

(n) laser welding the drawing conductors to the corresponding metal elements;

(o) insulating the welds by an insulating sheath;

(p) filling the cup terminal with cement and fitting on the housing tube;

(q) drying the cement;

(r) performing a functional test to check that no short circuits to ground of the elements occurred and that the thermopile has the proper electrical resistance.

According to an improvement there is provided a step of oxidizing the assembly of metal elements welded together and forming a corrugated or zig-zag element after step f) welding the metal elements to each other.

The metal wire with circular cross-section is cheaper than the rectangular cross-section wire.

The oxidized wire is sectioned into stubs of the same length, the stubs of a first metal material being the first elements and the stubs of the other metal material being the second elements forming the thermoelectric generator, namely the sequence of thermocouples connected in series to each other.

In said sequence the stubs of the two different metal materials are arranged alternate to each other and are aligned in length, namely of ends and transverse alignment, that is placing said stubs side by side.

Laser welding is performed for a given predetermined length of the ends of the stubs placed side by side and intended to form the first and second elements, with an alternate order of the welds according to which each stub is welded to the corresponding end of the immediately preceding stub by only one of its ends and to the corresponding end of the immediately following stub by only the other end.

Obviously even in this case it is possible and advantageous to perform the step of the second oxidation by heating at 850° the assembly of stubs welded together.

According to a further characteristic of the method, as the material filling the tubular case, glass powder is used, preferably in the form of a liquid mixture of water and glass powder.

The case, that is, the tube housing the corrugated element is filled with such mixture and, advantageously, in order to allow possible air bubbles captured inside the liquid to escape, the assembly of case, liquid and thermoelectric generator in the compacted condition is subjected to vibration.

Therefore, the filling material is solidified by baking the compacted assembly of housing case, filling material and thermoelectric generator at a temperature from 700° C. to 900° C. A pre-drying step can be possibly provided.

Thus, the compacted generator is held fixed inside the tubular housing case and moreover a covering is generated protecting the metal elements and particularly the constantan which is a typical metal used for one of the two types of metal elements.

According to another constructive feature of the thermopile and of the method of manufacturing it, it is advantageous to provide to wrap the compacted thermoelectric generator into an insulating jacket that separates it from the inner wall of the tubular housing case, improving the electric insulation, above all preventing it from disappearing over time deteriorating or compromising the functions of the thermopile.

Such insulating jacket has to exhibit contrasting characteristics since it must be resistant to high temperatures, particularly when there is provided a filling material for the tubular case comprising glass, and has to be melt at a temperature of about 700 to 900° C., but on the other side it must not affect thermal conductivity and, therefore, the heating and cooling of the thermoelectric generator within a time useful for the functions that it must carry out, namely, generating the electric driving force with intensity enough to energize the user device in presence of a heating source, such as a flame or the like and to stop the signal in short time when said heating source is interrupted.

The application of such insulating jacket can be performed on the thermoelectric generator in the compacted condition before being inserted in the housing case. The material can be already provided in the tube shape or it can be wrapped on the thermoelectric generator in the compacted condition and ready to be fitted in the tubular case.

An alternative to improve electric insulation of the corrugated element in the condition fitted in the housing tube, due to an electrically conductive contact that can be generated during the treatment between one or more of the metal elements and the inner wall of the housing tube, between such wall and the corrugated element wound on itself in the cylindrical shape is the fact of lining the inner wall of the housing tube with one or more layers of insulating cement subjected to drying before inserting the corrugated element.

A possible variant provides to use as a combination both the alternatives described above.

With reference to step filling and covering the individual metal elements inside the housing case, it is possible to take other materials such as for example ceramic, glass, epoxy glass, fiberglass, glass fiber or the like or mixtures of such materials.

Additional features and improvements are the subject matter of dependent claims.

### BRIEF DESCRIPTION OF THE DRAWINGS

Features of the invention and advantages deriving therefrom will be more clear from the following detailed description of the annexed figures, wherein:

FIG. 1 is a perspective view of a thermopile according to the invention;

FIG. 2 is a section according to a diametral plane parallel to the axis of the thermopile according to FIG. 1;

FIG. 3 is an exemplifying front view of one embodiment of the invention;

FIG. 4 is the perspective view of the detail “A” of the previous figure that is the junction region of the device;

FIG. 5 is a top view of the detail of FIG. 4;

FIG. 6 is a section view of a thermopile according to prior art;

FIG. 7 is a section view of a thermopile according to one embodiment of the invention.

### DETAILED DESCRIPTION OF EMBODIMENTS OF THE INVENTION

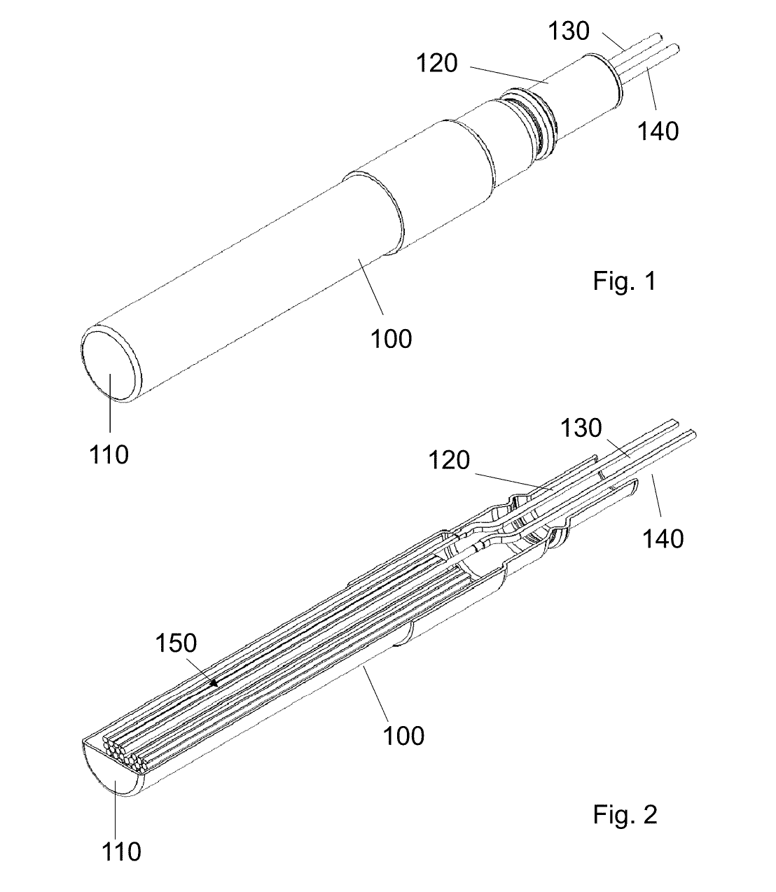

With reference to FIG. 1, a thermopile comprises a body composed of a tubular housing case 100 having a closed end 110 and that at the opposite end is closed by an end cap 120 which has a passageway for two output or drawing conductors 130 and 140 drawing the electric signal generated by the thermopile. Inside the tubular housing case 100 a thermoelectric generator 150 is housed which, as it will be disclosed below, is composed of a sequence of thermocouples. Such thermocouples are identical to each other and are interconnected in series. A first piece of an initial thermocouple of the sequence of thermocouples is laser welded to one of the two signal drawing conductors 130. An end element of the last thermocouple of the sequence of thermocouples is connected in turn to the second signal drawing conductor 140.

In order to allow signals with different potential difference to be drawn, it is possible to provide at least one further drawing conductor or several further drawing conductors (not shown) connected to different elements of the thermocouples provided in intermediate regions of the sequence of thermocouples.

According to a specific feature, the inner wall of the tubular case and/or that of the end cup or cap 120 closing it are lined with a layer of cement or the like forming an electrically insulating layer between said sequence of thermocouples and the inner wall of the housing case or tube.

Still according to an advantageous feature, the tubular housing case 100 is filled with glass material or the like that holds and makes integral with each other the thermoelectric generator 150, the case 100 and it also covers with a protection effect the elements composing the thermoelectric generator 150, with a particular reference to the protection of elements made of constantan.

Still according to another feature (not shown), it is also possible to provide, between the inner wall of the tubular housing case 100 and the thermoelectric generator 150 as well as the filling material, a jacket made of insulating material and resistant to high temperatures, such as for example a jacket in or made of insulating paper resistant to high temperatures, such as paper with a certain amount of mica.

The layer forming the jacket wrapping the thermoelectric generator 150 can be made in the form of a tube or in the form of a sheet wound around said thermoelectric generator 150.

Moreover such jacket can be provided as an alternative or in combination with the lining made of cement of the inner wall of the housing tube.

The filling material can be composed of glass, ceramic, epoxy glass, fiberglass, glass fiber or the like or mixtures of such materials.

The case 100 is made of a metal material.

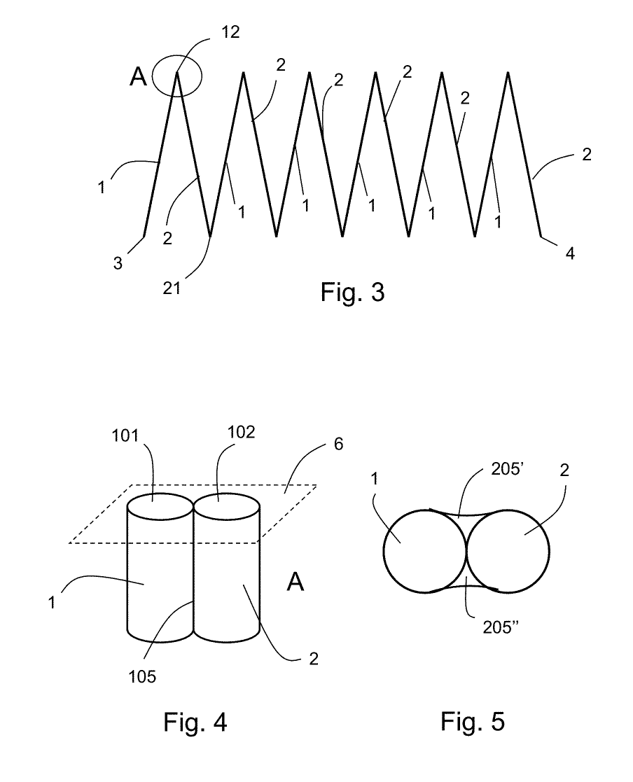

FIG. 3 shows in an exemplificative manner an assembly of pairs of different elements 1, 2 joined at the opposite ends to form a sequence of junctions of thermocouples 12 connected in series. The used materials are those conventionally used in thermocouples according to prior art such as for example, Chrome/Aluminum, Chrome/Constantan, Iron/Constantan, Nickel-Chrome-Silicon/Nickel-Silicon, Platinum/Rhodium, Iridium/Rhodium, Nickel/Molybdenum, Chromel/Constantan, Chromel/Alumel.

Each pair of elements 1, 2 is welded at one end 12. By welding also the opposite end 21, being careful to keep the alternate sequence of conductors of type 1 and those of type 2, a thermopile is obtained that simply is an assembly of thermocouples, the free ends of which are interconnected in series. Generally, the first and last terminal of the series 3, 4 are the output terminals of the thermopile, at which ends the voltage generated by Seeback effect is detected and to which the respective drawing conductors 130 and 140 of FIGS. 1 and 2 are welded. However, it is possible to provide also one or more output terminals connected to intermediate thermocouples, thus drawing a signal whose voltage corresponds to the unit voltage generated by a thermocouple multiplied by the number interposed between the end conductor and the intermediate signal drawing conductor.

Conductors are electrically insulated, for example by subjecting them to high temperature in oxidative environment and welded at the ends such to form thermocouple junctions.

The oxidation process can take place in two phases, a first phase of oxidation of the metal wires before sectioning them for forming the individual metal elements and a second oxidation phase after the individual metal elements are welded together and after completing the sequence of thermocouples, that is the thermoelectric generator.

FIG. 4 shows the detail of the junctions. Elements 1, 2 that have a circular or elliptical cross-section, are put side by side and caused to mate along a generating line 105 in proximity of an end. To this end a surface 6 can be used upon which the head surfaces 101, 102 of the elements 1, 2 are caused to abut such to guarantee an axial alignment.

There is no preferred position for the transverse alignment since the cylindrical symmetry allows the same superimposition surface to be obtained whatever the angle position of the parallel axis elements is. This is particularly important since, in thermopiles according to prior art, terminals forming junctions are flattened and therefore they need to be well aligned with each other both in axial and transverse direction such to guarantee them to be properly superimposed.

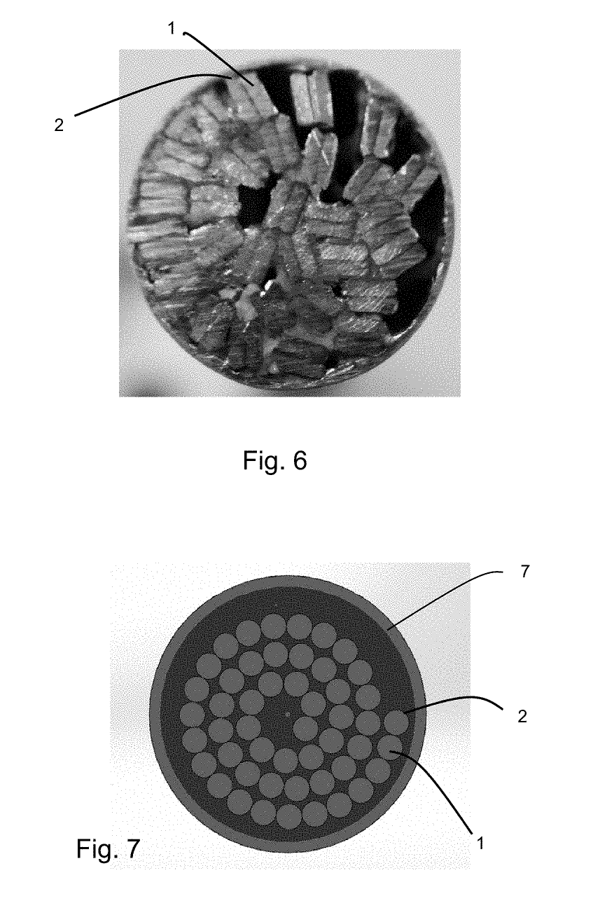

Thus, it is possible to create structures even with misaligned elements that is elements not lying all on the same plane. For the purposes of realization of the thermopile this does not involve particular drawbacks since the final device comprises a holding jacket 7, typically with a circular cross-section, where the conductors 1, 2 are fitted after having been suitably compacted and spirally wound. Angle misalignments between the elements lead to an irregular filling of the jacket, as pointed out in FIG. 7 with respect to the case of flat conductors shown in FIG. 6, an aspect that does not affect the operation of the device and that even allows a higher number of elements to be compacted thus increasing sensitivity.

The process of manufacturing the thermopile is described in detail above in the introduction description.

FIGS. 6 and 7 clarify well the concepts of the invention. The use of rounded conductor elements instead of flat ones, besides allowing the rolling step (to obtain flat terminals) and the positioning step (to obtain the exact superimposition of the terminals) to be eliminated, leads to the further advantage of allowing more reliable and quality welding to be performed.

With reference to prior art, the welding between different metals of the thermocouples occurs by melting them, generally without weld material for example by electric spot welding, in proximity of the contact points. In the case of flat conductors, the welding area has a shape following the profile of the contacts namely a rectangular shape. Moreover the melting will mainly occur at the area of the welding electrodes and also for a quite limited penetration depth in the thickness of the material. The areas surrounding the areas coinciding with the welding electrodes will be held one against the other by a simple contact, but they will not have constraints resulting from melted material and forming a kind of alloy.

By using a laser welding, on the contrary, if the electrodes have a cylindrical shape, the melted material pours into the gaps between the cylinders 205′, 205″ filling them as shown in FIG. 5.

Therefore by using the particular circular symmetry of the conductors it is possible to create a welding area containing an amount of melting material higher than the case of flat conductors considerably increasing the quality of the junction also as regards consumption of the electrodes, since the dimension of the volume where the melting generates an alloy between the two metals of the elements welded together is volumetrically higher and therefore it promotes the electrical contact.

The junction region of the ends of the conductors takes the shape of two semi-cylinders with circular or elliptical base joined along a generating line 105 with a gap between said semi-cylinders 205′, 205″ at least partially occupied by melting material resulting from welding. Thus a junction with a substantially oval cross-section is formed that is with arc portions joined by straight or curved lines 205, 205′.

The maximum efficiency is obtained by laser welding allowing the heat to be precisely directed by generating a higher amount of melt alloy inside the area 205′, 205″ between the two cylinders 1,2.

The use of laser has also the advantage of not having to entrust insulation of metal elements in the welded condition thereof. Electric spot welding requires, at least in the welding area, that the contact between the two parts to be welded is electrically conductive. If metal elements would be subjected to oxidation before being welded, by using the electric spot welding techniques it would be necessary to remove the layer of oxide at least in the welding areas and therefore an additional processing step should be added, for example using the process, defined as ROS (Remove Oxidation Sandblast), for removing oxide near the ends to guarantee the electric continuity necessary to the welding process by brazing or electric spot welding.

In order to avoid the above in known processes manufacturing thermopiles, the oxidation for generating the electric insulation layer of metal elements is performed with the elements in the welded condition.

This, however, causes the drawback that the formation of the oxide layer is not perfect, particularly in areas adjacent to the welding areas, since the two metal elements are very close if not in contact with each other in such areas, therefore, the oxidation treatment is not perfectly efficacious. This results in a possible electrically conductive contact between metal elements also in areas directly adjacent to welding areas and generates an extension of the contact areas in regard to the length of the metal elements, which is the same as shortening thereof and therefore as a reduction in resistance.

Therefore, each thermocouple generates a lower potential difference and in order to reach output signals with predetermined potential differences, in known thermopiles it is necessary to provide a higher number of metal elements with respect to elements necessary according to the present invention, with a reduction of the overall mass of the thermopile, less costs and more rapid response time.

The device according to the present invention can be widely changed as regards construction and can have many uses depending on the number of elements and on the type of used materials. In the field of burners, for example it is possible to obtain a good sensitivity by using 20 to 30, typically 25, thermocouples made of nickel-chrome/constantan with conductors with diameter of 0.6 to 1.0, typically 0.8 mm.

By using rounded cross-section conductors, the manufacturing process is considerably simplified, eliminating the step of rolling at least one of the two conductors and therefore the cost of wires of metal material, as well as eliminating, in the assembly process, also the steps required to properly orienting the conductors when placing them side-by-side for welding in the contact areas at the ends.

Laser welding provides wire oxidation before the step connecting the metal elements with each other, guaranteeing an electric insulation for all the length of the metal elements up to the welding area. This guarantees an optimal exploitation of thermoelectric capacities and therefore a higher efficiency of the generator as regards the voltage generated by the individual thermocouples, therefore, with the output voltage being the same, the number of elements of the generator is smaller than that of thermocouples of prior art.

Moreover, the melting generated by the laser produces an alloy between the two metals of the two conductors in the mutual joining area that makes the connection highly resistant from the mechanical perspective and from electrical conductivity perspective.

This is promoted also by the fact that the circular shape generates two recesses collecting the melted material that, therefore, is produced in an amount higher than electric welding techniques or brazing techniques (where even a third material is provided).

In this process, the advantage is also that while for the case of electric welding the two elements to be connected must be in contact with each other, therefore, the mutual positioning requires a certain degree of attention, in the case of laser welding the two areas to be connected can also be not in contact with each other, but simply put side-by-side.

The electrical contact between two metal elements therefore is better and has a lower resistance in the junction area, while in the immediately adjacent areas, the better and more accurate electrical insulation by the oxidation of the metal elements before being welded guarantees the fact that there are no contact areas outside the welding areas that limit the voltage generated by the pairs of metal elements.

All the above without departing from the information principle disclosed above and claimed below.

1. A thermoelectric device, particularly a thermopile, comprising:
at least a pair of different conductors composing a first and a second element (1, 2) and joined at one head end to form a thermocouple junction (12), opposite tail ends being free,
wherein said conductors (1, 2) have a circular or elliptical section, are arranged side-by-side in proximity of the head end, and are joined by laser welding.

2. The thermoelectric device according to claim 1, wherein the thermoelectric device comprises a plurality of pairs of conductors (1, 2) connected together by joining the tail ends of one conductor of a pair (1) with the tail end of the different conductor of another pair (2) to form a thermopile comprising thermocouple junctions (12, 21) in series, and wherein said plurality of pairs of conductors (1, 2) forms a thermoelectric generator.

3. The thermoelectric device according to claim 2, wherein different conductors of contiguous pairs (1,2) are arranged side-by-side in proximity of the tail ends (21) and with the head ends and/or tail ends (101, 102) substantially aligned with each other and joined by the laser welding.

4. The thermoelectric device according to claim 2, wherein a joining area of the head and/or tail ends of the conductors is shaped as two semi-cylinders with a circular or elliptical base joined along a generating line (105) with a gap between said semi cylinders (205′, 205″) at least partially occupied by melting material resulting from the laser welding to form a substantially oval section junction.

5. The thermoelectric device according to claim 2, further comprising a containment enclosure (7, 100), and housing the conductors (1, 2), the containment enclosure having a closed head end (110) receiving the head ends (12) of the pairs of conductors (1, 2) and closed, at a side of the tail ends (21), by a cap-shaped terminal (120) provided with passages for at least two signal drawing conductors (130, 140), thus forming a thermopile, the conductors being covered by insulating material and arranged in side-by-side relation, the first (3) and at least the last conductor (4) of the series being output terminals of the thermoelectric device connected to said signal drawing conductors.

6. The thermoelectric device according to claim 5, wherein the containment enclosure (7) is a circular or elliptical section jacket, said thermocouples in series being spirally wound and being housed inside the containment enclosure.

7. The thermoelectric device according to claim 5, wherein the containment enclosure is filled with insulating material composed, as desired, of one of the following materials: ceramic, glass, epoxy glass, fiberglass, glass fiber, or a mixture thereof.

8. The thermoelectric device according to claim 5, wherein within the containment enclosure (7, 100) housing the thermoelectric generator there is provided a jacket made of an electrically insulating material composed of a layer of insulating cement applied on an inner wall of the containment enclosure (7, 100) or an insulating material covering said thermocouples shaped as a tube or sheet wrapped around said thermocouples or a combination thereof.

9. The thermoelectric device according to claim 1, further comprising a plurality of different elongated conductor elements (1, 2) forming first and second different adjacent elements that are joined together at opposite ends to form thermocouple junctions (21, 21), wherein the elongated conductor elements (1, 2) have a circular or elliptical section and are joined by laser welding without weld material.

10. A method of manufacturing thermopiles comprising:
(a) providing two metal wires made of a different material with a round, circular or elliptical section, and for each wire performing the following treatments:
(b) washing the wires;
(c) straightening the wires;
(d) oxidizing and cutting to size the two metal wires;
(e) mating with each other metal elements obtained from the two wires in a sequence of metal elements side-by-side made of a different metal, alternately with each other;
(f) laser welding ends of said metal elements for a given length of end portions;
(g) winding to form a corrugated or zig-zag element;
(h) performing a stabilization thermal treatment, which includes baking for stabilizing in a tubular or cylindrical shape the corrugated or zig-zag element;
(i) providing a housing tube and insulating the housing tube;
(j) inserting incoherent or fluid insulating material in the housing tube;
(k) inserting the wound or zig-zag corrugated element stabilized with the cylindrical shape in the housing tube;
(l) optionally, vibrating the housing tube with the insulating material and the corrugated element inserted and strengthening by a heat treatment of the insulating material;
(m) preparing drawing conductors together with a fastening nut and pre-inserting into a closing terminal of the housing tube shaped as a cap or cup;
(n) laser welding the drawing conductors to the corresponding metal elements;
(o) insulating the welds with an insulating sheath;
(p) filling the cup terminal with cement and fitting on the housing tube; and
(q) drying the cement.

11. The method according to claim 10, wherein step (j) is performed according to the following steps in alternative or in combination with each other:
(i1) lining an inner wall of the housing tube with a layer of high temperature cement and then drying the high temperature cement;
(i2) lining the inner wall of the housing tube with mica-based insulating paper with a high temperature resistance.

12. The method according to claim 10, further comprising an end step (r) that comprise performing a functional test to check that no short circuits to ground of the metal elements have occurred and that the thermopile has a predetermined electrical resistance.

13. The method according to claim 10, further comprising a step of oxidizing the metal elements welded together and forming an element corrugated or with a zig-zag pattern following step (f) to weld the metal elements with each other.

14. The method according to claim 10, wherein the incoherent or fluid insulating material is composed of ceramic, glass, epoxy glass, fiberglass, glass fiber, a mixture thereof in granular form or mixed to a liquid carrier.
